(19) United States
(12) Patent Application Publication
(10) Pub. No.: US 2023/0146017 A1
(43) Pub. Date: May 11, 2023

(54) COMPARATOR CIRCUIT

(71) Applicant: ROHM CO., LTD., Kyoto (JP)

(72) Inventors: Akio SASABE, Kyoto (JP); Daiki YANAGISHIMA, Kyoto (JP)

(73) Assignee: ROHM CO., LTD., Kyoto (JP)

(21) Appl. No.: 17/913,586

(22) PCT Filed: Feb. 8, 2021
(86) PCT No.: PCT/JP2021/004604

§ 371 Date: Sep. 22, 2022

(30) Foreign Application Priority Data
Mar. 30, 2020 (JP) 2020-060599

(51) Int. Cl. H03K 5/08; G01K 7/01; H03K 5/24

(52) U.S. Cl. CPC H03K 5/08; G01K 7/01; H03K 5/2472

(57) ABSTRACT

A comparator circuit includes a first comparator configured to receive input of an input signal and a comparison target signal to be compared with the input signal, a first output stage including an N-channel transistor having a control terminal to which a first control terminal voltage output from the first comparator is applied, and a first clamp unit configured to limit the first control terminal voltage to be not higher than a first predetermined voltage that is higher than a first threshold voltage of the N-channel transistor but is lower than a first high side voltage output as high level from the first comparator when the first control terminal voltage is not limited.

### TECHNICAL FIELD

The present invention relates to a comparator circuit.

### BACKGROUND ART

One example of conventional temperature sensing devices is disclosed in Patent Document 1 identified below. In the temperature sensing device of Patent Document 1, a diode is used as a temperature sensor. This temperature sensing device senses temperature by utilizing the characteristic that when a constant current is fed to a diode, the value of the forward voltage of the diode changes with temperature.

### CITATION LIST

### Patent Literature

Patent Document 1: Japanese unexamined patent application publication No. 2012-227517

### SUMMARY OF INVENTION

### Technical Problem

Conventional temperature sensing devices that use a diode as a temperature sensor as described above include a comparator circuit that uses a forward voltage generated in the diode as a temperature sensing voltage and compares the temperature sensing voltage with a triangular wave signal. This comparator circuit outputs a pulse signal with a duty ratio commensurate with temperature.

Here, in the above-described comparator circuit, there is a demand for adapting to a wider range of levels of an input signal as a target of comparison with the triangular wave signal. This problem, however, is not confined to comparator circuits for use in temperature sensing devices.

In light of the foregoing, an object of the present invention is to provide a comparator circuit capable of adapting to a wider range of an input signal.

### Solution to Problem

According to one aspect of the present invention, a comparator circuit includes a first comparator configured to receive input of an input signal and a comparison target signal to be compared with the input signal, a first output stage including an N-channel transistor having a control terminal to which a first control terminal voltage output from the first comparator is applied, and a first clamp unit configured to limit the first control terminal voltage to be not higher than a first predetermined voltage that is higher than a first threshold voltage of the N-channel transistor but is lower than a first high side voltage output as high level from the first comparator when the first control terminal voltage is not limited (a first configuration).

In the first configuration described above, preferably, the first predetermined voltage has a value twice the first threshold voltage (a second configuration).

In the first or second configuration described above, preferably, the comparison target signal is a triangular wave signal (a third configuration).

In any one of the first to third configurations described above, preferably, the first output stage includes a first constant current source connected to the N-channel transistor on a higher potential side than the N-channel transistor (a fourth configuration).

In any one of the first to fourth configurations described above, preferably, the first clamp unit includes a diode-connected NMOS transistor (a fifth configuration).

Preferably, any one of the first to fifth configurations described above further includes a second comparator configured to receive input of the input signal and the comparison target signal, a second output stage including a P-channel transistor having a control terminal to which a second control terminal voltage output from the second comparator is applied, a second clamp unit configured to limit the second control terminal voltage to be not lower than a second predetermined voltage that is lower than a third threshold voltage lower, by a second threshold voltage of the P-channel transistor, than a second high side voltage output as high level from the second comparator but is higher than a low level voltage output as low level from the second comparator when the second control terminal voltage is not limited, and an output unit configured to generate a third output signal on detecting whichever of rising timing/falling timing of each of a first output signal of the first output stage and a second output signal of the second output stage is earlier (a sixth configuration).

According to another aspect of the present invention, a comparator circuit includes a second comparator configured to receive input of an input signal and a comparison target signal to be compared with the input signal, a second output stage including a P-channel transistor having a control terminal to which a second control terminal voltage output from the second comparator is applied, and a second clamp unit configured to limit the second control terminal voltage to be not lower than a second predetermined voltage that is lower than a third threshold voltage lower, by a second threshold voltage of the P-channel transistor, than a second high side voltage output as high level from the second comparator but is higher than a low level voltage output as low level from the second comparator when the second control terminal voltage is not limited (a seventh configuration).

In the seventh configuration described above, preferably, the second predetermined voltage is lower than the second high side voltage by a voltage twice the second threshold voltage (an eighth configuration).

In the seventh or eighth configuration described above, preferably, the comparison target signal is a triangular wave signal (a ninth configuration).

In any one of the seventh to ninth configurations described above, preferably, the second output stage includes a second constant current source connected to the P-channel transistor on a lower potential side than the P-channel transistor (a tenth configuration).

In any one of the seventh to tenth configurations described above, preferably, the second clamp unit includes a diode-connected PMOS transistor (an eleventh configuration).

According to still another aspect of the present invention, a temperature monitor circuit includes the comparator circuit having any one of the above-described configurations, and a constant current circuit configured to feed a constant current to a diode. Here, the input signal is a signal based on a forward voltage of the diode (a twelfth configuration).

According to yet another aspect of the present invention, an IC package includes the temperature monitor circuit having the configuration described above, a pulse generator configured to generate a pulse based on a temperature sensing signal output from the temperature monitor circuit, an isolation transformer configured to transmit the pulse, and a logic unit configured to operate such that a temperature output signal is externally output from an external terminal based on the pulse transmitted by the isolation transformer (a thirteenth configuration).

### Advantageous Effects of Invention

According to the present invention, a comparator circuit can adapt to a wider range of the input signal.

### BRIEF DESCRIPTION OF DRAWINGS

FIG. 1 is a diagram showing a configuration of a gate driver according to an exemplary embodiment of the present invention.

FIG. 2 is a diagram showing an internal configuration example of a temperature monitor circuit.

FIG. 3A is a circuit diagram showing a configuration of a comparator circuit according to a first comparative example.

FIG. 3B is a circuit diagram showing a configuration of a comparator circuit according to a first embodiment.

FIG. 3C is a diagram showing a specific example of a clamp unit in FIG. 3B.

FIG. 4A is a timing chart showing an operation example in the comparator circuit according to the first comparative example (a case with a comparatively low input signal).

FIG. 4B is a timing chart showing an operation example in the comparator circuit according to the first comparative example (a case with a comparatively high input signal).

FIG. 5A is a timing chart showing an operation example in the comparator circuit according to the first embodiment (a case with a comparatively low input signal).

FIG. 5B is a timing chart showing an operation example in the comparator circuit according to the first embodiment (a case with a comparatively high input signal).

FIG. 6A is a circuit diagram showing a configuration of a comparator circuit according to a second comparative example.

FIG. 6B is a circuit diagram showing a configuration of a comparator circuit according to a second embodiment.

FIG. 6C is a diagram showing a specific example of a clamp unit in FIG. 6B.

FIG. 7A is a timing chart showing an operation example in the comparator circuit according to the second comparative example (a case with a comparatively low input signal).

FIG. 7B is a timing chart showing an operation example in the comparator circuit according to the second comparative example (a case with a comparatively high input signal).

FIG. 8A is a timing chart showing an operation example in the comparator circuit according to the second embodiment (a case with a comparatively low input signal).

FIG. 8B is a timing chart showing an operation example in the comparator circuit according to the second embodiment (a case with a comparatively high input signal).

FIG. 9 is a circuit diagram showing a configuration of a comparator circuit according to a third embodiment.

### DESCRIPTION OF EMBODIMENTS

Hereinafter, exemplary embodiments of the present invention will be described with reference to the accompanying drawings.

<Configuration of Gate Driver>

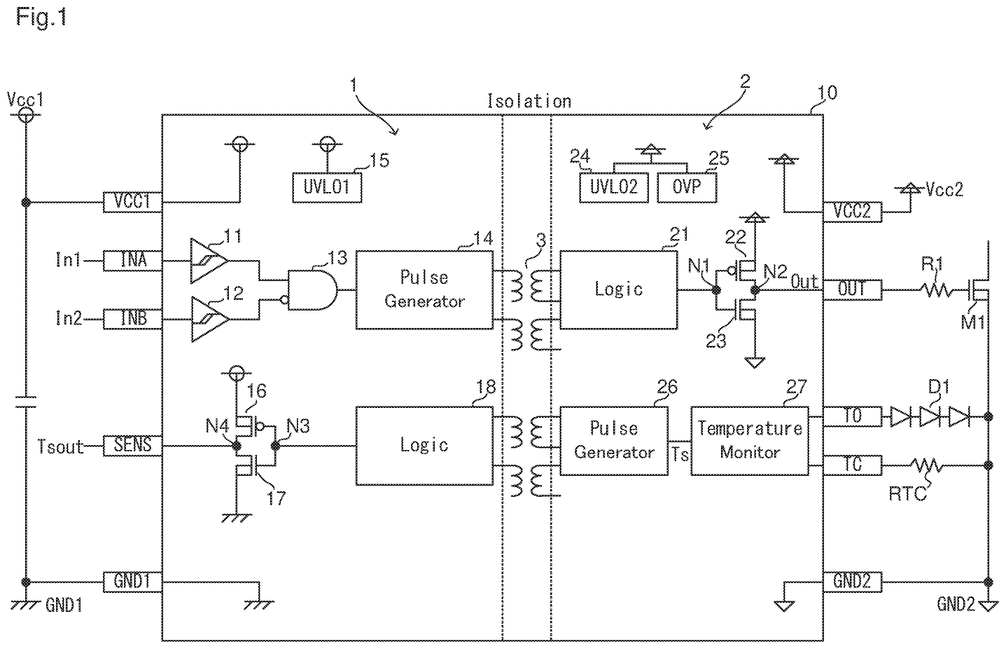

FIG. 1 is a diagram showing a configuration of a gate driver 10 according to an exemplary embodiment of the present invention. As shown in FIG. 1, the gate driver 10 is a device that drives the gate of an NMOS transistor M1.

The gate driver 10 includes a primary side circuit 1, a secondary side circuit 2, and an isolation transformer 3. The gate driver 10 is an IC package that includes, as external terminals (lead terminals) for establishing external electric connection, a VCC1 terminal, an INA terminal, an INB terminal, a SENS terminal, a GND1 terminal, a VCC2 terminal, an OUT terminal, a TO terminal, a TC terminal, and a GND2 terminal.

The primary side circuit 1 includes a first Schmitt trigger 11, a second Schmitt trigger 12, an AND circuit 13, a pulse generator 14, a first under voltage lock out (UVLO) unit 15, a PMOS transistor 16, an NMOS transistor 17, and a logic unit 18.

The secondary side circuit 2 includes a logic unit 21, a PMOS transistor 22, an NMOS transistor 23, a second UVLO unit 24, an overvoltage protection (OVP) unit 25, a pulse generator 26, and a temperature monitor circuit 27.

The isolation transformer 3 is disposed so as to connect the primary side circuit 1 and the secondary side circuit 2. The isolation transformer 3, while isolating the primary side circuit 1 and the secondary side circuit 2 from each other, transmits a signal coming from one of the primary side circuit 1 and the secondary side circuit 2 to the other.

The first UVLO unit 15 monitors a power supply voltage Vcc1 applied to the VCC1 terminal, and shuts down the primary side circuit 1 when the power supply voltage Vcc1 falls to be lower than a predetermined voltage.

The first Schmitt trigger 11 transmits a first input signal In1, which is externally fed to the INA terminal, to a first input terminal of the AND circuit 13. The second Schmitt trigger 12 transmits a second input signal In2, which is externally fed to the INB terminal, to a second input terminal of the AND circuit 13.

The AND circuit 13 takes the logical product of the level of a signal fed to the first input terminal and a level obtained by inverting the level of a signal fed to the second input terminal. Accordingly, in cases where the first input signal In1 is at low level and the second input signal In2 is at low level, where the first input signal In1 is at low level and the second input signal In2 is at high level, and where the first input signal In1 is at high level and the second input signal In2 is at high level, the output of the AND circuit 13 is at low level, while, in a case where the first input signal In1 is at high level and the second input signal In2 is at low level, the output of the AND circuit 13 is at high level.

The pulse generator 14, with a fall of the output of the AND circuit 13 from high level to low level as a trigger, generates a pulse with a width narrower than that of the output of the AND circuit 13, and outputs the generated pulse to the primary side of the isolation transformer 3. The pulse fed to the primary side of the isolation transformer 3 causes a change in current, whereby, on the secondary side of the isolation transformer 3, a current is generated, and this current is fed to the logic unit 21. In this case, a high-level signal is output from the logic unit 21 to be fed to the gate of the PMOS transistor 22 and to the gate of the NMOS transistor 23.

Here, the PMOS transistor 22 (a switch element) and the NMOS transistor 23 (a switch element) are connected in series between a power supply voltage Vcc2, which is applied to the VCC2 terminal, and a second ground GND2, which is applied to the GND2 terminal, and thereby form a switching arm. Specifically, the source of the PMOS transistor 22 is connected to the application terminal for the power supply voltage Vcc2. The drain of the PMOS transistor 22 is connected to the drain of the NMOS transistor 23 at node N2. The source of the NMOS transistor 23 is connected to the application terminal for the second ground GND2.

Node N1, at which the gate of the PMOS transistor 22 and the gate of the NMOS transistor 23 are connected, is connected to the output terminal of the logic unit 21.

Node N2 is connected to the OUT terminal. To the OUT terminal, one end of a resistor R1 is externally connected. The other end of the resistor R1 is connected to the gate of the NMOS transistor M1. The source of the NMOS transistor M1 is externally connected to the GND2 terminal. Note that the second ground GND2, serving as a reference voltage for the secondary side circuit 2, is different from a first ground GND1, which is applied to the GND1 terminal to serve as a reference voltage for the primary side circuit 1.

Here, in a case where, as described previously, a high-level signal from the logic unit 21 is applied to node N1, the PMOS transistor 22 is turned off, the NMOS transistor 23 is turned on, and an output voltage Out, which is a voltage of the OUT terminal, becomes the second ground GND2 (low level). Accordingly, the NMOS transistor M1 is turned off.

By contrast, the pulse generator 14, with a rise of the output of the AND circuit 13 from low level to high level as a trigger, generates a pulse with a width narrower than that of the output of the AND circuit 13, and outputs the generated pulse to the primary side of the isolation transformer 3. The pulse fed to the primary side of the isolation transformer 3 causes a change in current, whereby, on the secondary side of the isolation transformer 3, a current is generated, and this current is fed to the logic unit 21. In this case, a low-level signal is output from the logic unit 21 to be applied to node N1.

In this case, the PMOS transistor 22 is turned on, the NMOS transistor 23 is turned off, and the output voltage Out becomes the power supply voltage Vcc2 (high level). Accordingly, the NMOS transistor M1 is turned on.

Here, the target transistor to be driven by the gate driver 10 may be constituted by an IGBT instead of the NMOS transistor M1. In that case, the other end of the resistor R1 is connected to the gate of the IGBT, and the GND2 terminal is connected to the emitter of the IGBT.

The second UVLO unit 24 monitors the power supply voltage Vcc2, which is applied to the VCC2 terminal, and when the power supply voltage Vcc2 falls to be lower than a predetermined voltage, the second UVLO unit 24 shuts down the secondary side circuit 2. The OVP unit 25 is a circuit that senses an overvoltage of the power supply voltage Vcc2.

To the TO terminal, the anode of a diode D1 is externally connected. Here, the diode D1 may be constituted by a plurality of elements as shown in FIG. 1, or may instead be constituted by a single element. The cathode of the diode D1 is externally connected to the GND2 terminal.

To the TC terminal, one end of a resistor RTC is connected. The other end of the resistor RTC is externally connected to the GND2 terminal.

The temperature monitor circuit 27 is a circuit that senses temperature by using the diode D1 as a temperature sensor. The resistor RTC is an element that sets the current value of a constant current generated in the temperature monitor circuit 27.

The temperature monitor circuit 27 outputs, to the pulse generator 26, a sensed temperature as a temperature sensing signal Ts, which is a pulse signal. The pulse generator 26, similarly to the pulse generator 14 described previously, generates a pulse with a width shorter than that of the pulse signal (the temperature sensing signal Ts) fed from the temperature monitor circuit 27, and outputs the generated pulse to the secondary side of the isolation transformer 3. The pulse fed to the secondary side of the insulation transformer 3 causes a change in current, whereby, on the primary side of the insulation transformer 3, a current is generated, and this current is fed to the logic unit 18. In this case, a high-level or low-level signal is output from the logic unit 18 to be fed to the gate of the PMOS transistor 16 and to the gate of the NMOS transistor 17.

Here, the PMOS transistor 16 (a switch element) and the NMOS transistor 17 (a switch element) are connected in series between a power supply voltage Vcc1, which is applied to the VCC1 terminal, and a first ground GND1, which is applied to the GND1 terminal, and thereby form a switching arm. Specifically, the source of the PMOS transistor 16 is connected to the application terminal for the power supply voltage Vcc1. The drain of the PMOS transistor 16 is connected to the drain of the NMOS transistor 17 at node N4. The source of the NMOS transistor 17 is connected to the application terminal for the first ground GND1.

Node N3, at which the gate of the PMOS transistor 16 and the gate of the NMOS transistor 17 are connected, is connected to the output terminal of the logic unit 18. Node N4 is connected to the SENS terminal.

Based on a pulse output from the logic unit 18, by the switching arm constituted by the PMOS transistor 16 and the NMOS transistor 17, a temperature output signal Tsout, which is a pulse signal, is externally output from the SENS terminal. In this manner, temperature information sensed by the diode D1 serving as a temperature sensor can be output outside the IC. Note that the first input signal In1, the second input signal In2, and the temperature output signal Tsout are communicated, for example, between an electronic control unit (ECU) (not shown) outside the IC (the gate driver 10) and the IC.

<Configuration of Temperature Monitor Circuit>

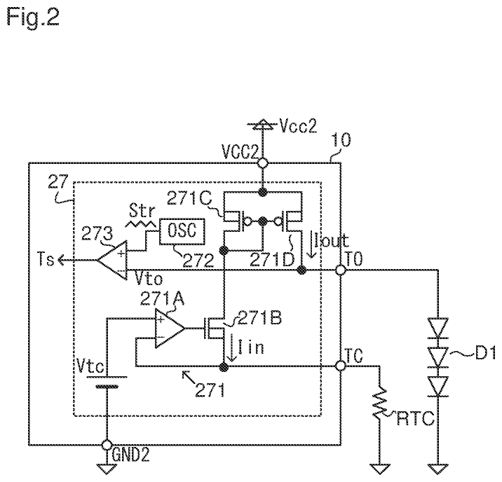

FIG. 2 is a diagram showing an internal configuration example of the temperature monitor circuit 27. The temperature monitor circuit 27 shown in FIG. 2 includes a constant current circuit 271, an oscillator 272, and a comparator circuit 273.

The constant current circuit 271 includes an error amplifier 271A, an NMOS transistor 271B, and POS transistors 271C and 271D.

To the non-inverting input terminal (+) of the error amplifier 271A, a reference voltage Vtc is applied. To the inverting input terminal (−) of the error amplifier 271A, via the TC terminal, the one end of the resistor RTC is connected. The output terminal of the error amplifier 271A is connected to the gate of the NMOS transistor 271B. The source of the NMOS transistor 271B is connected to the TC terminal.

The PMOS transistors 271C and 271D constitute a current mirror. Specifically, the gate and the drain of the PMOS transistor 271C are short-circuited. The drain of the PMOS transistor 271C is connected to the drain of the NMOS transistor 271B. The gate of the PMOS transistor 271C is connected to the gate of the PMOS transistor 271D. The sources of the PMOS transistors 271C and 271D are connected to the VCC2 terminal. The drain of the PMOS transistor 271D is connected to the TO terminal.

With this configuration, control is performed such that the voltage of the TC terminal agrees with the reference voltage Vtc, and through the NMOS transistor 271B passes a constant current Iin with a current value determined by the reference voltage Vtc and a resistance value Rtc of the resistor RTC. Then, by the current mirror constituted by the PMOS transistors 271C and 271D, the constant current Iin has its current value increased by 10 times, for example, to become a constant current Tout to be fed from the TO terminal to the diode D1. That is, the constant current circuit 271 generates the constant current Tout to be fed to the diode D1.

The diode D1 has a characteristic that, under a constant current, its forward voltage decreases as temperature rises. Accordingly, the temperature can be sensed by feeding the constant current Tout to the diode D1 serving as a temperature sensor and measuring the forward voltage generated in the diode D1.

The comparator circuit 273 compares a voltage Vto of the TO terminal generated as the forward voltage of the diode D1 with a triangular wave signal Str generated by the oscillator 272, and outputs, as a comparison result, the temperature sensing signal Ts, which is a pulse signal. The temperature sensing signal Ts is a pulse signal with a duty ratio corresponding to the sensed temperature.

<First Embodiment of Comparator Circuit>

Next, descriptions will be given of various embodiments of the comparator circuit 273 in the temperature monitor circuit 27.

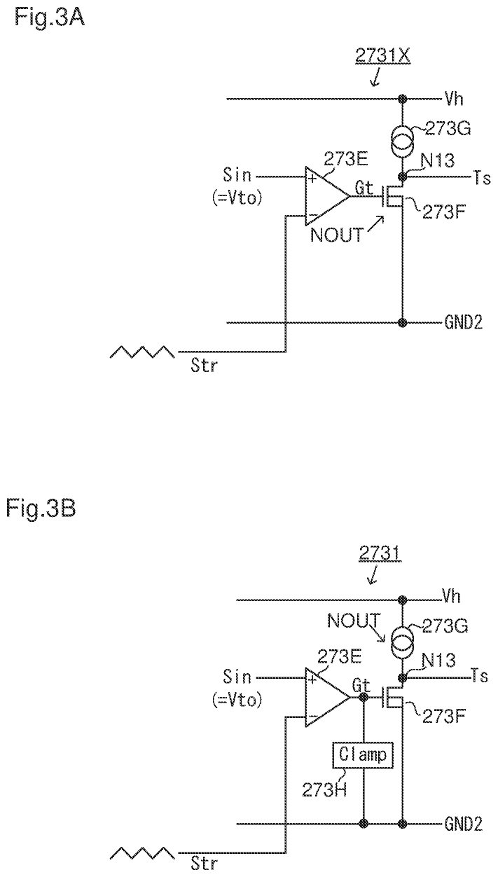

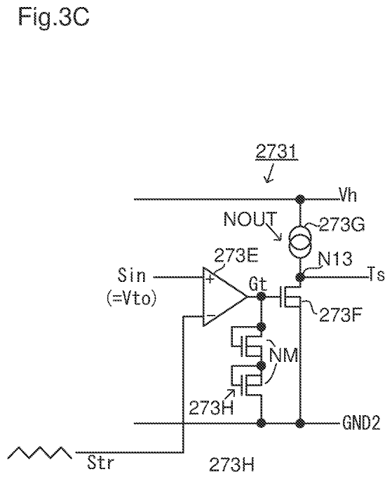

First, a first embodiment of the comparator circuit 273 will be described. FIG. 3A is a circuit diagram showing a configuration of a comparator circuit 2731X according to a first comparative example presented for better understanding of the characteristics of the first embodiment of the comparator circuit 273.

As shown in FIG. 3A, the comparator circuit 2731X according to the first comparative example includes a comparator 273E, an NMOS transistor 273F (an N-channel transistor), and a constant current source 273G. The NMOS transistor 273F and the constant current source 273G constitute an output stage NOUT. FIG. 3A also shows a line to which the second ground GND2 is applied and a line to which a predetermined high side voltage Vh, which is a voltage higher than the second ground GND2, is applied. Here, the high side voltage Vh is, for example, a predetermined internal voltage Vreg, which is generated based on the power supply voltage Vcc2.

To the non-inverting input terminal (+) of the comparator 273E, the voltage Vto (see FIG. 2) of the TO terminal is fed as an input signal Sin. To the inverting input terminal (—) of the comparator 273E, the triangular wave signal Str is fed. The comparator 273E compares the input signal Sin with the triangular wave signal Str, and outputs a gate signal (a control terminal voltage) Gt as a comparison result to the gate (a control terminal) of the NMOS transistor 273F. That is, the triangular wave signal Str is an example of a comparison target signal to be compared with the input signal Sin.

The source of the NMOS transistor 273F is connected to an application terminal for a second ground GND2. The constant current source 273G is disposed between an application terminal for the high side voltage Vh and the drain of the NMOS transistor 273F. The NMOS transistor 273F is turned on/off in accordance with the gate signal Gt, and thereby, at node N13, at which the constant current source 273G and the drain of the NMOS transistor 273F are connected, the temperature sensing signal Ts is generated. That is, from the output stage NOUT, the temperature sensing signal Ts is output.

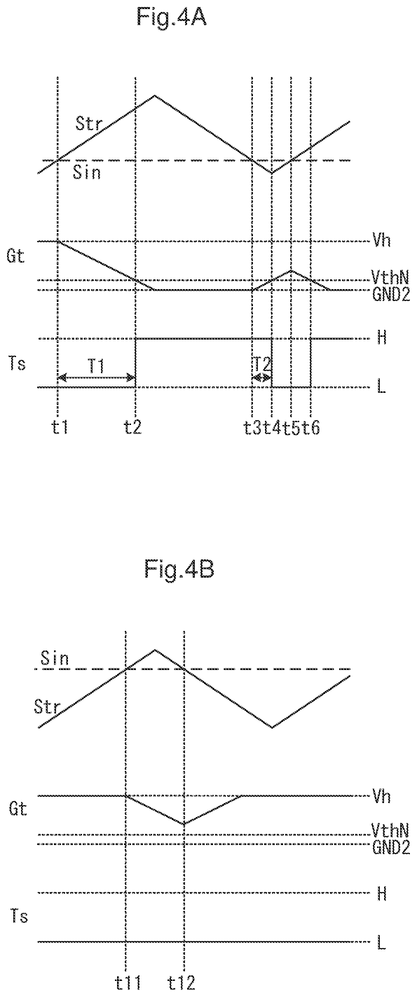

Now, a description will be given of an operation of the thus-configured comparator circuit 2731X according to the first comparative example, with reference to timing charts shown in FIG. 4A and FIG. 4B.

In both FIG. 4A and FIG. 4B, in the order from the top stage, waveforms of the input signal Sin, the triangular wave signal Str, the gate signal Gt, and the temperature sensing signal Ts are shown. This also applies to other timing charts to be described later.

In both FIG. 4A and FIG. 4B, together with the gate signal Gt, a threshold voltage VthN of the NMOS transistor 273F is also shown. There is a larger voltage difference between the threshold voltage VthN and the high side voltage Vh than between the threshold voltage VthN and the second ground GND2.

FIG. 4A is a timing chart showing an example of a case where the input signal Sin is comparatively low. In this case, at timing t1, at which the triangular wave signal Str rises to cross the input signal Sin from below to above the input signal Sin, the gate signal Gt starts to fall from high level (the high side voltage Vh) toward low level (the second ground GND2). Then, when the gate signal Gt reaches the threshold voltage VthN at timing t2, the NMOS transistor 273F is turned off, and the temperature sensing signal Ts rises to high level. Thereafter, the gate signal Gt continues to fall and reaches low level.

Thereafter, at timing t3, at which the triangular wave signal Str falls to cross the input signal Sin from above to below the input signal Sin, the gate signal Gt starts to rise toward high level. Then, when the gate signal Gt reaches the threshold voltage VthN at timing t4, the NMOS transistor 273F is turned on, and the temperature sensing signal Ts falls to low level.

Thereafter, at timing t5, at which the triangular wave signal Str rises to cross the input signal Sin from below to above the input signal Sin, the gate signal Gt starts to fall toward low level. Then, when the gate signal Gt reaches the threshold voltage VthN at timing t6, the NMOS transistor 273F is turned off, and the temperature sensing signal Ts rises to high level. Thereafter, the gate signal Gt continues to fall and reaches low level.

In this manner, in the example shown in FIG. 4A, by comparison between the input signal Sin and the triangular wave signal Str, the temperature sensing signal Ts is generated which is a pulse signal including high level and low level. However, since the voltage difference between the threshold voltage VthN and the high side voltage Vh is larger than the voltage difference between the threshold voltage VthN and the second ground GND2, delay time T1 (timing t1 to timing t2) until the temperature sensing signal Ts rises when the triangular wave signal Str crosses the input signal Sin to above becomes longer than delay time T2 (timing t3 to timing t4) until the temperature sensing signal Ts falls when the triangular wave signal Str crosses the input signal Sin to below, and thus there is a large delay time difference.

FIG. 4B is a timing chart showing an example of a case where the input signal Sin is comparatively high. In this case, at timing t11, at which the triangular wave signal Str rises to cross the input signal Sin from below to above the input signal Sin, the gate signal Gt starts to fall toward low level.

Thereafter, at timing t12, the triangular wave signal Str falls to cross the input signal Sin from above to below the input signal Sin, but the comparatively high input signal Sin causes the time period from timing t11 to timing t12 to be short, so that the gate signal Gt starts to rise before reaching the threshold voltage VthN. Accordingly, the NMOS transistor 273F remains on, and thus the temperature sensing signal Ts remains at low level. Thereafter, the gate signal Gt reaches high level.

In this manner, the example shown in FIG. 4B suffers a disadvantage that although the triangular wave signal Str has crossed the input signal Sin to above the input signal Sin, the temperature sensing signal Ts does not rise to high level.

Thus, a comparator circuit 2731 according to the first embodiment of the present invention has a configuration as shown in FIG. 3B. The comparator circuit 2731 shown in FIG. 3B is different in configuration from the comparator circuit 2731x according to the first comparative example in that the comparator circuit 2731 includes a clamp unit 273H.

The clamp unit 273H has a function of limiting the gate signal Gt to be not higher than a first predetermined voltage V1 that is lower than the high side voltage Vh but is higher than the threshold voltage VthN. FIG. 3C shows an example of a specific configuration of the clamp unit 273H. In FIG. 3C, the clamp unit 273H is constituted by a diode-connected NMOS transistor NM. The clamp unit 273H may be constituted otherwise, for example, by a Zener diode, etc.

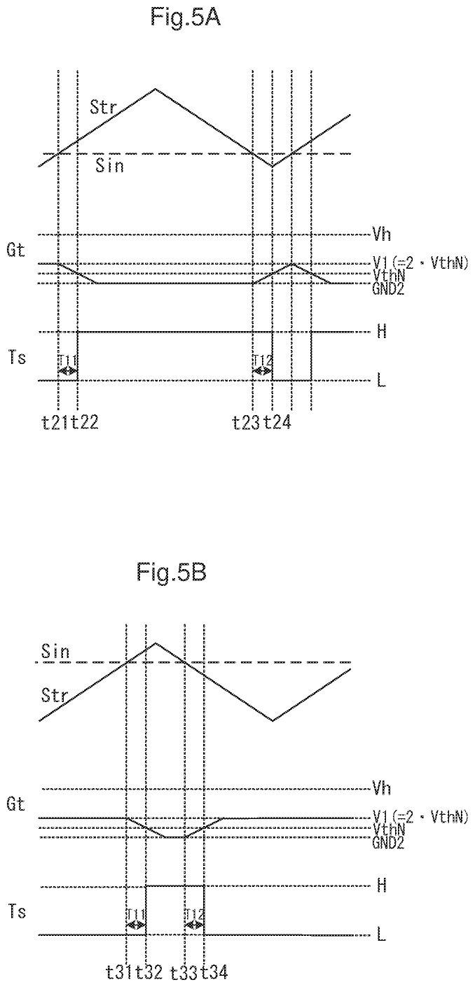

Now, a description will be given of an operation of the thus-configured comparator circuit 2731 according to the first embodiment, with reference to the timing charts shown in FIG. 5A and FIG. 5B. In FIG. 5A and FIG. 5B, together with the gate signal Gt, the first predetermined voltage V1 is also shown. Here, the first predetermined voltage V1 has, as a preferable value, a value (2·VthN) twice the threshold voltage VthN.

FIG. 5A shows a case where the input signal Sin is comparatively low, and corresponds to FIG. 4A according to the first comparative example described previously. In this case, at timing t21, at which the triangular wave signal Str rises to cross the input signal Sin from below to above the input signal Sin, the gate signal Gt starts to fall toward low level from the first predetermined voltage V1 which is a limit of the gate signal Gt set by the clamp unit 273H. Then, when the gate signal Gt reaches the threshold voltage VthN at timing t22, the NMOS transistor 273F is turned off, and the temperature sensing signal Ts rises to high level. Thereafter, the gate signal Gt continues to fall and reaches low level.

Thereafter, at timing t23, at which the triangular wave signal Str falls to cross the input signal Sin from above to below the input signal Sin, the gate signal Gt starts to rise toward high level. Then, when the gate signal Gt reaches the threshold voltage VthN at timing t24, the NMOS transistor 273F is turned on, and the temperature sensing signal Ts falls to low level.

In this manner, by having the gate signal Gt limited, by the clamp unit 273H, to be not higher than the first predetermined voltage V1, it is possible to reduce the difference between the voltage difference between the first predetermined voltage V1 and the threshold voltage VthN and the voltage difference between the threshold voltage VthN and the second ground GND2, and thus it is possible to reduce the delay time difference between delay time T11 (timing t21 to timing t22) until the temperature sensing signal Ts rises when the triangular wave signal Str crosses the input signal Sin to above the input signal Sin and delay time T12 (timing t23 to timing t24) until the temperature sensing signal Ts falls when the triangular wave signal Str crosses the input signal Sin to below the input signal Sin. In particular, in FIG. 5A, the first predetermined voltage V1 is set equal to 2 VthN, this delay time difference can be reduced to approximately zero.

FIG. 5B shows a case where the input signal Sin is comparatively high, and corresponds to FIG. 4B according to the first comparative example described previously. In this case, at timing t31, at which the triangular wave signal Str rises to cross the input signal Sin from below to above the input signal Sin, the gate signal Gt starts to fall toward low level from the first predetermined voltage V1 which is a limit of the gate signal Gt set by the clamp unit 273H. Then, when the gate signal Gt reaches the threshold voltage VthN at timing t32, the NMOS transistor 273F is turned off, and the temperature sensing signal Ts rises to high level. Thereafter, the gate signal Gt continues to fall and reaches low level.

Thereafter, at timing t33, at which the triangular wave signal Str falls to cross the input signal Sin from above to below the input signal Sin, the gate signal Gt starts to rise toward high level. Then, when the gate signal Gt reaches the threshold voltage VthN at timing t34, the NMOS transistor 273F is turned on, and the temperature sensing signal Ts falls to low level.

In this manner, in FIG. 5B, unlike in FIG. 4B, at timing t31, the gate signal Gt starts to fall from the first predetermined voltage V1, and thus, although the time period from timing t31 to timing t33 is short, the gate signal Gt can reach the threshold voltage VthN at timing t32. Accordingly, the temperature sensing signal Ts can rise to high level. Further, similarly to in FIG. 5A, it is possible to reduce the delay time difference between delay time T11 and delay time T12.

In this manner, with the comparator circuit 2731 according to this embodiment, regardless of whether the input signal Sin is high or low, the temperature sensing signal Ts can be generated properly, and thus it is possible to adapt to a wider range of the input signal Sin.

<Second Embodiment of Comparator Circuit>

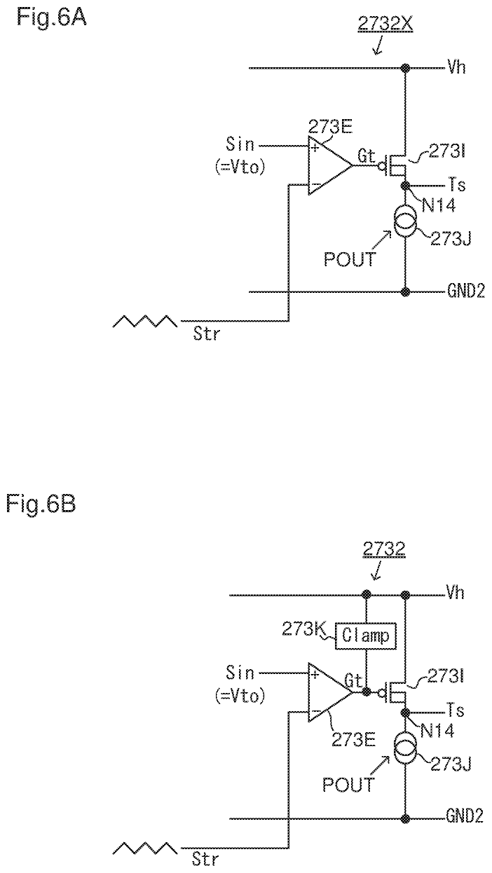

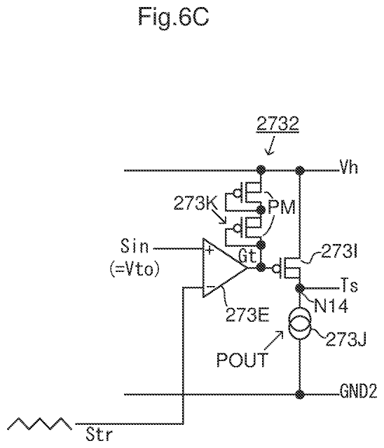

Next, a second embodiment of the comparator circuit will be described. FIG. 6A is a circuit diagram showing a configuration of a comparator circuit 2732X according to a second comparative example, which is provided for better understanding of the characteristics of the second embodiment of the comparator circuit 273.

The comparator circuit 2732X according to the second comparative example is different in configuration from the first comparative example (FIG. 3A) in that the comparator circuit 2732X includes a PMOS transistor 273I (a P-channel transistor) and a constant current source 273J that constitute an output stage POUT. Specifically, to the gate (a control terminal) of the PMOS transistor 273I, the gate signal (the control terminal voltage) Gt, which is output from the comparator 273E, is applied. The source of the PMOS transistor 273I is connected to the application terminal for the high side voltage Vh. The constant current source 273J is disposed between the drain of the PMOS transistor 273I and the application terminal for the second ground GND2. At node N14, at which the drain of the PMOS transistor 273I and the constant current source 273J are connected, the temperature sensing signal Ts is generated. That is, from the output stage POUT, the temperature sensing signal Ts is output.

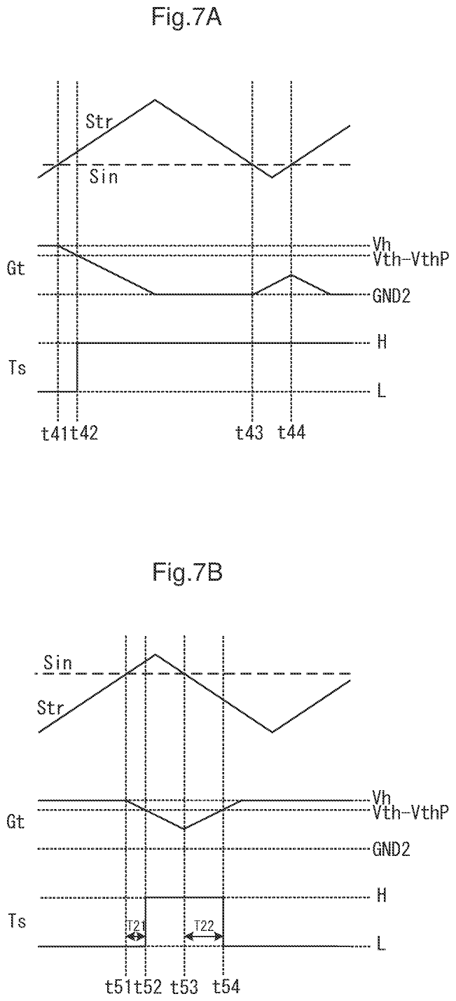

Now, a description will be given of an operation of the thus-configured comparator circuit 2732X according to the second comparative example, with reference to timing charts shown in FIG. 7A and FIG. 7B.

In FIG. 7A and FIG. 7B, together with the gate signal Gt, a threshold voltage (Vh−VthP) is also shown which is a voltage lower than the high side voltage Vh by a threshold voltage VthP of the PMOS transistor 273I. The voltage difference between the threshold voltage (Vh−VthP) and the high side voltage Vh is smaller than the voltage difference between the threshold voltage (Vh−VthP) and the second ground GND2.

FIG. 7A is a timing chart showing an example of a case where the input signal Sin is comparatively low. In this case, at timing t41 at which the triangular wave signal Str rises to cross the input signal Sin from below to above the input signal Sin, the gate signal Gt starts to fall from high level (the high side voltage Vh) toward low level (the second ground GND2). Then, when the gate signal Gt reaches the threshold voltage (Vh−VthP) at timing t42, the PMOS transistor 273I is turned on and the temperature sensing signal Ts rises to high level. Thereafter, the gate signal Gt continues to fall and reaches low level.

Thereafter, at timing t43 at which the triangular wave signal Str falls to cross the input signal Sin from above to below the input signal Sin, the gate signal Gt starts to rise toward high level. Thereafter, at timing t44, the triangular wave signal Str crosses the input signal Sin from below to above the input signal Sin. The comparatively low input signal Sin causes the time period between timing t43 and timing t44 to be short, so that the gate signal Gt starts to fall before reaching the threshold voltage (Vh−VthP). Accordingly, the PMOS transistor 273I remains on, and thus the temperature sensing signal Ts remains at high level. Thereafter, the gate signal Gt reaches low level.

In this manner, the example shown in FIG. 7A suffers a disadvantage that although the triangular wave signal Str has crossed the input signal Sin to below the input signal Sin, the temperature sensing signal Ts does not fall to low level.

FIG. 7B is a timing chart showing an example of a case where the input signal Sin is comparatively high. In this case, at timing t51, at which the triangular wave signal Str rises to cross the input signal Sin from below to above the input signal Sin, the gate signal Gt starts to fall from high level toward low level. Then, when the gate signal Gt reaches the threshold voltage (Vh−VthP) at timing t52, the PMOS transistor 273I is turned on, and the temperature sensing signal Ts rises to high level. Thereafter, the gate signal Gt continues to fall.

Thereafter, at timing t53, at which the triangular wave signal Str falls to cross the input signal Sin from above to below the input signal Sin, the gate signal Gt starts to rise toward high level. Then, when the gate signal Gt reaches the threshold voltage (Vh−VthP) at timing t54, the PMOS transistor 273I is turned off, and the temperature sensing signal Ts falls to low level. Thereafter, the gate signal Gt continues to rise and reaches high level.

In this manner, in the example shown in FIG. 7B, the voltage difference between the threshold voltage (Vh−VthP) and the high side voltage Vh is smaller than the voltage difference between the threshold voltage (Vh−VthP) and the second ground GND2, and thus delay time T21 (timing t51 to timing t52) until the temperature sensing signal Ts rises when the triangular wave signal Str crosses the input signal Sin to above the input signal Sin is shorter than delay time T22 (timing t53 to timing t54) until the temperature sensing signal Ts falls when the triangular wave signal Str crosses the input signal Sin to below the input signal Sin, and thus there is a large delay time difference.

Thus, a comparator circuit 2732 according to the second embodiment of the present invention has a configuration as shown in FIG. 6B. The comparator circuit 2732 shown in FIG. 6B is different in configuration from the comparator circuit 2732X according to the second comparative example in that the comparator circuit 2732 includes a clamp unit 273K.

The clamp unit 273K has a function of limiting the gate signal Gt to be not lower than a second predetermined voltage V2 that is lower than the threshold voltage (Vh−VthP) but higher than the second ground GND2 (a low level voltage). FIG. 6C shows an example of a specific configuration of the clamp unit 273K. In FIG. 6C, the clamp unit 273K is constituted by the diode-connected PMOS transistor PM. The clamp unit 273K can be constituted otherwise, and for example, it may be constituted by a Zener diode, etc.

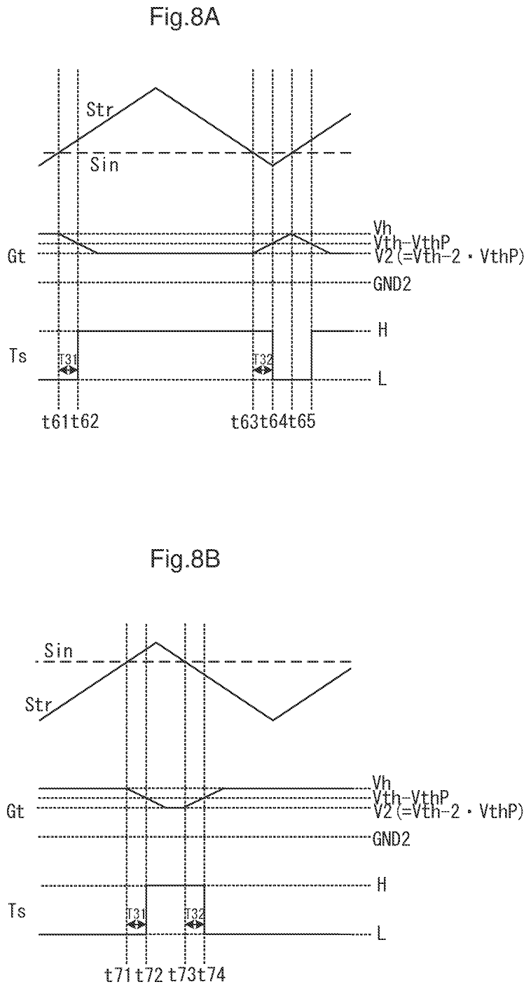

Now, a description will be given of an operation of the thus-configured comparator circuit 2732 according to the second embodiment, with reference to the timing charts shown in FIG. 8A and FIG. 8B. In FIG. 8A and FIG. 8B, together with the gate signal Gt, the second predetermined voltage V2 is also shown. Here, the second predetermined voltage V2 has, as a preferable value, a voltage that is lower than the high side voltage Vh by a value twice the threshold voltage VthP (2·VthP).

FIG. 8A shows a case where the input signal Sin is comparatively low, and corresponds to FIG. 7A according to the second comparative example described previously. In this case, at timing t61, at which the triangular wave signal Str rises to cross the input signal Sin from below to above the input signal Sin, the gate signal Gt starts to fall from high level toward low level. Then, when the gate signal Gt reaches the threshold voltage (Vh−VthP) at timing t62, the PMOS transistor 273I is turned on, and the temperature sensing signal Ts rises to high level. Thereafter, the gate signal Gt continues to fall to be limited to be equal to the second predetermined voltage V2.

Thereafter, at timing t63, at which the triangular wave signal Str falls to cross the input signal Sin from above to below the input signal Sin, the gate signal Gt starts to rise toward high level. Then, when the gate signal Gt reaches the threshold voltage (Vh−VthP) at timing t64, the PMOS transistor 273I is turned off, and the temperature sensing signal Ts falls to low level.

Thereafter, at timing t65, the triangular wave signal Str rises to cross the input signal Sin from below to above the input signal Sin, and thus the gate signal Gt starts to fall toward low level.

In this manner, in FIG. 8A, unlike in FIG. 7A, at timing t63, the gate signal Gt starts to rise from the second predetermined voltage V2, and thus, although the time period from timing t63 to timing t65 is short, the gate signal Gt can reach the threshold voltage (Vh−VthP) at timing t64. Accordingly, the temperature sensing signal Ts can fall to low level.

Further, by having the gate signal Gt limited, by the clamp unit 273K, to be not lower than the second predetermined voltage V2, it is possible to reduce the difference between the voltage difference between the threshold voltage (Vh−VthP) and the high side voltage Vh and the voltage difference between the threshold voltage (Vh−VthP) and the second predetermined voltage V2, and thus it is possible to reduce the delay time difference between delay time T31 (timing t61 to timing t62) until the temperature sensing signal Ts rises when the triangular wave signal Str crosses the input signal Sin to above the input signal Sin and delay time T32 (timing t63 to timing t64) until the temperature sensing signal Ts falls when the triangular wave signal Str crosses the input signal Sin to below the input signal Sin. In particular, in FIG. 8A, the second predetermined voltage V2 is set equal to V2−2·VthP, this delay time difference can be reduced to approximately zero.

FIG. 8B shows a case where the input signal Sin is comparatively high, and corresponds to FIG. 7B according to the second comparative example described previously. In this case, at timing t71, at which the triangular wave signal Str rises to cross the input signal Sin from below to above the input signal Sin, the gate signal Gt starts to fall from high level toward low level. Then, when the gate signal Gt reaches the threshold voltage (Vh−VthP) at timing t72, the PMOS transistor 273I is turned on, and the temperature sensing signal Ts rises to high level. Thereafter, the gate signal Gt continues to fall to be limited to be equal to the second predetermined voltage V2.

Thereafter, at timing t73 at which the triangular wave signal Str falls to cross the input signal Sin from above to below the input signal Sin, the gate signal Gt starts to rise toward high level. Then, when the gate signal Gt reaches the threshold voltage (Vh−VthP) at timing t74, the PMOS transistor 273I is turned off, and the temperature sensing signal Ts falls to low level.

In the case of FIG. 8B, similarly to the case of FIG. 8A, it is possible to reduce the delay time difference between delay time T31 and delay time T32.

In this manner, the comparator circuit 2732 according to this embodiment can also generate proper temperature sensing signal Ts regardless of whether the input signal Sin is high or low, and thus can adapt to a wider range of the input signal Sin.

<Third Embodiment of Comparator Circuit>

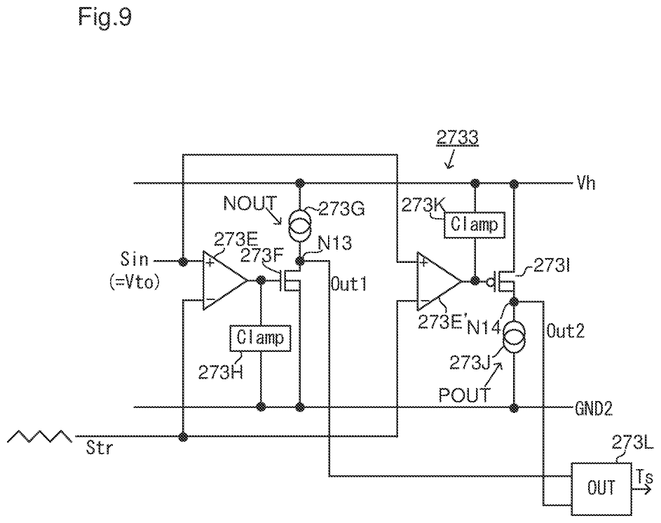

Next, a third embodiment of the comparator circuit 273 will be described. FIG. 9 is a circuit diagram showing a configuration of a comparator circuit 2733 according to the third embodiment.

In this embodiment, to the configuration of the first embodiment described previously, the configuration of the second embodiment is added. That is, as shown in FIG. 9, the comparator circuit 2733 includes, in addition to the configuration of the first embodiment, the configuration of the second embodiment (a comparator 273E′, the PMOS transistor 273I, the constant current source 273J, and the clamp unit 273K).

The input signal Sin and the triangular wave signal Str are both fed to the comparator 273E′ as well as to the comparator 273E.

The comparator circuit 2733 further includes an output unit 273L. The output unit 273L receives a first output signal Out1 generated at node N13 and a second output signal Out2 generated at node 14, and the output unit 273L outputs the temperature sensing signal Ts (a third output signal). The output unit 273L raises the temperature sensing signal Ts at whichever of rising timing of the first output signal Out1 and rising timing of the second output signal Out2 is earlier, and lowers the temperature sensing signal Ts at whichever of falling timing of the first output signal Out1 and falling timing of the second output signal Out2 is earlier.

For example, in a case where the input signal Sin is comparatively low, the comparator circuit 2733 operates as shown in FIG. 5A and FIG. 8A described previously, and the temperature sensing signal Ts shown in FIG. 5A corresponds to the first output signal Out1, and the temperature sensing signal Ts shown in FIG. 8A corresponds to the second output signal Out2.

Regarding the rising of the output signals, the output stage POUT constituted by the PMOS transistor 273I and the constant current source 273J is faster in operation speed than the output stage NOUT constituted by the NMOS transistor 273F and the constant current source 273G. Regarding the falling of the output signals, the output stage NOUT is faster in operation speed than the output stage POUT.

Accordingly, the timing (t62 in FIG. 8A) of rising of the second output signal Out2 is a little earlier than the timing (t22 in FIG. 5A) of rising of the first output signal Out1, and thus at the timing of rising of the second output signal Out2, the temperature sensing signal Ts is raised. Further, the timing (t24 in FIG. 5A) of falling of the first output signal Out1 is a little earlier than the timing (t64 in FIG. 8A) of falling of the second output signal Out2, and thus at the timing of falling of the first output signal Out1, the temperature sensing signal Ts is lowered.

### OTHERS

It should be understood that the above embodiments are examples in all respects and are not limiting; the technological scope of the present invention is not indicated by the above description of the embodiments but by the claims; and all modifications within the scope of the claims and the meaning equivalent to the claims are covered.

### INDUSTRIAL APPLICABILITY

The present invention is usable in temperature monitor circuits, for example.

### REFERENCE SIGNS LIST

10 gate driver
1 primary side circuit
11 first Schmitt trigger
12 second Schmitt trigger
13 AND circuit
14 pulse generator
15 first UVLO unit
16 PMOS transistor
17 NMOS transistor
18 logic unit
2 secondary side circuit
21 logic unit
22 PMOS transistor
23 NMOS transistor
24 second UVLO unit
25 OVP unit
26 pulse generator
27 temperature monitor circuit
271 constant current circuit
271A error amplifier
271B NMOS transistor
271C, 271D PMOS transistor
272 oscillator
273, 2731, 2731X, 2732, 2732X, 2733 comparator circuit
273E comparator
273F NMOS transistor
273G constant current source
273H clamp unit
273I PMOS transistor
273J constant current source
273K clamp unit
273L output unit
NOUT, POUT output stage
R1, RTC resistor
M1 NMOS transistor
D1 diode

1. A comparator circuit, comprising:
a first comparator configured to receive input of an input signal and a comparison target signal to be compared with the input signal;
a first output stage including an N-channel transistor having a control terminal to which a first control terminal voltage output from the first comparator is applied; and
a first clamp unit configured to limit the first control terminal voltage to be not higher than a first predetermined voltage that is higher than a first threshold voltage of the N-channel transistor but is lower than a first high side voltage output as high level from the first comparator when the first control terminal voltage is not limited.

2. The comparator circuit according to claim 1, wherein the first predetermined voltage has a value twice the first threshold voltage.

3. The comparator circuit according to claim 1, wherein the comparison target signal is a triangular wave signal.

4. The comparator circuit according to claim 1, wherein the first output stage includes a first constant current source connected to the N-channel transistor on a higher potential side than the N-channel transistor.

5. The comparator circuit according to claim 1, wherein the first clamp unit includes a diode-connected NMOS transistor.

6. The comparator circuit according to claim 1, further comprising:
a second comparator configured to receive input of the input signal and the comparison target signal;
a second output stage including a P-channel transistor having a control terminal to which a second control terminal voltage output from the second comparator is applied;
a second clamp unit configured to limit the second control terminal voltage to be not lower than a second predetermined voltage that is lower than a third threshold voltage lower, by a second threshold voltage of the P-channel transistor, than a second high side voltage output as high level from the second comparator but is higher than a low level voltage output as low level from the second comparator when the second control terminal voltage is not limited; and
an output unit configured to generate a third output signal on detecting whichever of rising timing/falling timing of each of a first output signal of the first output stage and a second output signal of the second output stage is earlier.

7. A comparator circuit, comprising:
a second comparator configured to receive input of an input signal and a comparison target signal to be compared with the input signal;
a second output stage including a P-channel transistor having a control terminal to which a second control terminal voltage output from the second comparator is applied; and
a second clamp unit configured to limit the second control terminal voltage to be not lower than a second predetermined voltage that is lower than a third threshold voltage lower, by a second threshold voltage of the P-channel transistor, than a second high side voltage output as high level from the second comparator but is higher than a low level voltage output as low level from the second comparator when the second control terminal voltage is not limited.

8. The comparator circuit according to claim 7, wherein the second predetermined voltage is lower than the second high side voltage by a voltage twice the second threshold voltage.

9. The comparator circuit according to claim 7, wherein the comparison target signal is a triangular wave signal.

10. The comparator circuit according to claim 7, wherein the second output stage includes a second constant current source connected to the P-channel transistor on a lower potential side than the P-channel transistor.

11. The comparator circuit according to claim 7, wherein the second clamp unit includes a diode-connected PMOS transistor.

12. A temperature monitor circuit, comprising:
the comparator circuit according to claim 1; and
a constant current circuit configured to feed a constant current to a diode;
wherein the input signal is a signal based on a forward voltage of the diode.

13. An IC package, comprising:
the temperature monitor circuit according to claim 12;
a pulse generator configured to generate a pulse based on a temperature sensing signal output from the temperature monitor circuit;
an isolation transformer configured to transmit the pulse; and
a logic unit configured to operate such that a temperature output signal is externally output from an external terminal based on the pulse transmitted by the isolation transformer.
